(19) United States
(12) Patent Application Publication
(10) Pub. No.: US 2025/0226787 A1
(43) Pub. Date: Jul. 10, 2025

(54) VEHICLE WINDOW COMPRISING A SOLAR CELL ARRANGEMENT

(71) Applicant: Webasto SE, Stockdorf (DE)

(72) Inventor: Rupert KOGLER, Stockdorf (DE)

(21) Appl. No.: 18/853,051

(22) PCT Filed: Mar. 3, 2023
(86) PCT No.: PCT/EP2023/055421

§ 371 Date: Sep. 30, 2024

(30) Foreign Application Priority Data
Apr. 21, 2022 (DE) 10 2022 109 693.9

(51) Int. Cl. H02S 20/30; B32B 27/30; B60J 7/047; B60R 16/03; H02S 40/22; H10F 77/50

(52) U.S. Cl. CPC H02S 20/30; B32B 27/30; B60J 7/047; B60R 16/03; H02S 40/22; H10F 77/50; B32B 2250/40; B32B 2255/20; B32B 2255/205; B32B 2307/412; B32B 2307/416; B32B 2605/00

(57) ABSTRACT

A vehicle window having a sandwich structure having an outer window body facing a vehicle environment and an inner window body facing a vehicle interior and having a solar cell arrangement, which is disposed between the outer window body and the inner window body, whose upper surface faces the outer window body and whose lower surface faces the inner window body and which has several solar cell elements, between which spaces are formed. At least one reflective layer is disposed on the side of the solar cell arrangement facing away from the outer window body and which reflects radiation, which passes through the spaces between the solar cell elements starting from the vehicle environment, at least partly in the direction of the solar cell elements.

### CROSS-REFERENCE TO RELATED APPLICATIONS

This application is a U.S. national phase application filed under 35 U.S.C. § 371 of International Application No. PCT/EP2023/055421, filed on Mar. 3, 2023, published under WO 2023/202815 A1 on Oct. 26, 2023, designating the United States, which claims priority from German Patent Application Number 10 2022 109 693.9, filed on Apr. 21, 2022, which are hereby incorporated herein by reference in their entirety.

### FIELD

A vehicle window having the features of the preamble of claim 1.

### BACKGROUND

A vehicle window of this kind is known from DE 10 2012 101 245 A1 and forms a sandwich structure which comprises an outer window body facing a vehicle environment and an inner window body facing a vehicle interior. A solar cell arrangement, which can be used to generate electricity and can be connected to consumer loads of the vehicle in question, is disposed between the outer window body and the inner window body. The vehicle window can in particular be part of a vehicle roof and a movable lid element of a roof opening system or also be a fixed roof element which is disposed rigidly relative to a vehicle carcass. The solar cell arrangement, which can be formed by several crystalline, thin-film solar cells, is laminated between the outer window body and the inner window body. Depending on the distance between the solar cells, a partial view through the vehicle window is possible. The unfilled space between the solar cells in turn reduces the power yield of the solar cell arrangement.

### SUMMARY

The present embodiments are a vehicle window of the kind mentioned above which allows light to enter the vehicle interior while the power yield achievable by the solar cell arrangement is also increased compared to known vehicle windows.

According to the presented embodiments, this object is attained by the vehicle window having the features of claim 1.

Thus, the invention proposes a vehicle window which comprises a composite structure which has an outer window body facing a vehicle environment and an inner window body facing a vehicle interior, and also a solar cell arrangement which is disposed between the outer window body and the inner window body. The solar cell arrangement comprises several solar cell elements which are disposed next to each other in the longitudinal or transverse direction of the window, so that spaces are formed between the solar cell elements. At least one reflective layer is provided, which is disposed on the side of the solar cell arrangement facing away from the outer window body and which reflects the radiation, which passes through the spaces between the solar cell elements starting from the vehicle environment, at least partially in the direction of the solar cell elements. By the reflective layer, therefore, a bifacial solar cell arrangement is created which also uses radiation, which strikes the lower surfaces of the solar cell elements, to generate electricity. Radiation can strike both the upper surface and the lower surface of the solar cell arrangement. Radiation reflected by the reflective layer thus contributes to the energy yield of the solar cell arrangement.

In particular, the reflective layer can be at least partially transparent for visible light, i.e., for light in the wavelength range between 400 nm and 800 nm, whereas radiation outside this wavelength range is reflected by the reflective layer.

The solar cell arrangement can be provided with what is known as a capsule film on its upper surface and on its lower surface. The capsule films are lamination films via which the solar cell arrangement is connected to the adjacent window bodies, i.e., the outer window body and the inner window body.

In a specific embodiment of the vehicle window according to the invention, the reflective layer is disposed on a capsule film which is adjacent to the solar cell arrangement. Advantageously, the capsule film with the reflective layer is the capsule film which is disposed on the lower surface of the solar cell arrangement or on the side of the solar cell arrangement facing away from the vehicle environment.

In a further specific embodiment of the vehicle window according to the invention, the reflective layer is disposed on a surface of the inner window body facing the solar cell arrangement or also on a surface of the inner window body facing away from the solar cell arrangement.

Irrespective of the arrangement of the reflective layer, the light passing from above through the spaces between the solar cell elements is reflected at this layer depending on the wavelength range and thus directed towards the lower surface of the solar cell arrangement.

The reflective layer can be a vapor deposit coating which is applied to the relevant side of the inner window body and/or the capsule film. The vapor deposit coating can be applied using a CVD (chemical vapor deposition) process or a PVD (physical vapor deposition) process.

However, it is also conceivable that the reflective layer comprises a film, meaning that the reflective layer is formed by a film, which in turn is reflective for certain wavelength ranges due to its material properties, or which has a vapor deposit coating itself, said vapor deposit coating having reflective properties.

For example, as reflective medium, the reflective layer comprises a metal, in particular silver, and/or a metal oxide, in particular ITO (indium tin oxide).

In order to keep the power yield of the vehicle window according to the invention as high as possible, at least the capsule film facing the vehicle environment is transparent to UV radiation. In particular, this capsule film is made of what is known as solar PVB (PVB=polyvinyl butyral).

In a further specific embodiment of the vehicle window according to the invention, the outer window body is modified in terms of its refractive index in a surface area on its side facing the vehicle environment in order to increase the power yield by means of the solar cell arrangement. This can be achieved in particular by providing the outer window body with a hardened sol-gel coating on the side facing the vehicle environment. The sol-gel coating, which in particular comprises a silicon oxide compound, helps to minimize the reflection of radiation on the outside of the window. After application, the sol-gel coating is solidified by means of a chemical reaction. The porosity of the solidified sol-gel coating determines the refractive index and thus the optical behavior of the outer window body.

In order to give the vehicle window a design adapted to the vehicle structure in question, the sandwich structure can be provided with a glass frit on its side facing the vehicle interior, at least in certain areas. The glass frit prevents vehicle structures below the glass frit from being visible from the outside of the window.

It is conceivable that the glass frit forms the reflective layer. Advantageously, however, the reflective layer is located between the glass frit and the solar cell arrangement. For example, a multilayer, in which one layer forms the reflective layer and the other layer forms the glass frit, can also be formed on the inside or lower surface of the inner window body, so that the reflective layer is disposed between the glass frit and the inner window body.

In addition to the reflective layer, the vehicle window according to the invention can also have other coatings. For example, it is conceivable to arrange what is known as a low-E coating or thermal coating which reflects infrared radiation in the direction of the vehicle interior on the inside of the inner window body.

The vehicle window according to the invention is in particular a vehicle roof element, which can be a fixed roof element or also a movable lid element of a roof opening system. However, it is also conceivable that the vehicle window according to the invention is a windshield, a rear window or a side window of the vehicle in question.

Further advantages and advantageous embodiments of the object of the invention can be found in the description, the drawing and the patent claims.

### BRIEF DESCRIPTIONS OF THE DRAWINGS

Exemplary embodiments of a vehicle window according to the invention are illustrated schematically simplified in the drawing and are explained in more detail in the following description.

FIG. 1 is a schematic top view of a vehicle roof having vehicle windows according to the invention;

FIG. 2 is a sectional perspective view of a vehicle window according to the invention;

FIG. 3 is a sectional view of the vehicle window according to FIG. 2;

FIG. 4 is a sectional view of an alternative embodiment of a vehicle window; and

FIG. 5 is a sectional view of another alternative embodiment of a vehicle window.

### DETAILED DESCRIPTION

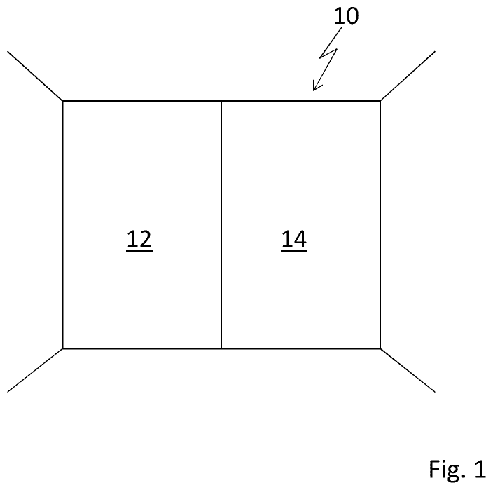

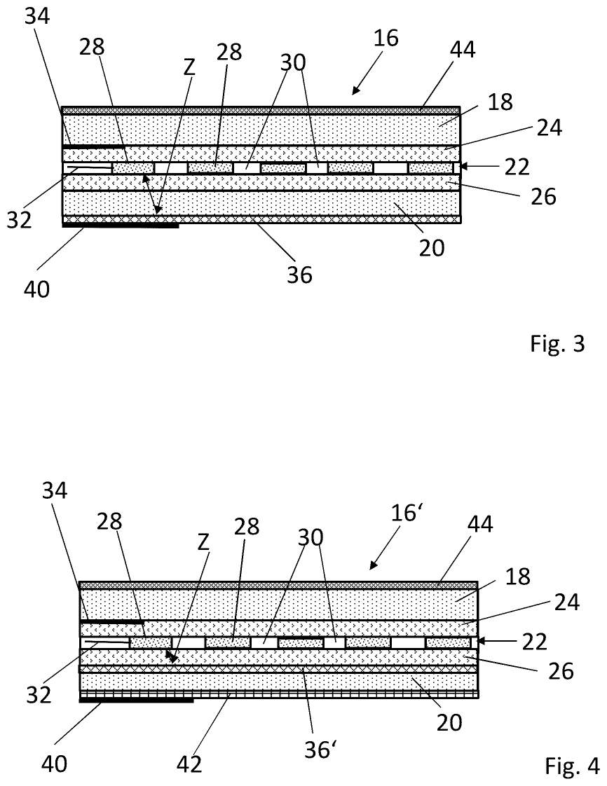

FIGS. 1 to 3 show a vehicle roof arrangement 10 of an otherwise not further shown motor vehicle, said vehicle roof arrangement 10 comprising an adjustable lid element 12, which is part of a roof opening system, and a fixed roof element 14, which is fixedly or immovably connected to the vehicle body. Lid element 12 and fixed roof element 14 each represent a vehicle window having a sandwich structure 16, which is shown in particular in FIG. 3. Alternatively, vehicle roof arrangement 10 can have a second fixed roof element instead of lid element 12 or only a single fixed roof element extending over the entire surface instead of the fixed roof element and the lid element.

Each sandwich structure 16 of roof elements 12 and 14 comprises an outer window body 18, which is curved and made of clear glass. In addition, sandwich structure 16 comprises an inner window body 20, which is also curved and can be made of tinted glass. Outer window body 18 is disposed on the side of vehicle roof arrangement 10 facing the vehicle environment and inner window body 20 is disposed on the side of vehicle roof arrangement 10 facing the vehicle interior.

A solar cell arrangement 22 is accommodated between outer window body 18 and inner window body 20, said solar cell arrangement 22 being limited on both sides by a capsule film 24 or 26, which is made of what is known as a solar PVB material which has a high transmission capacity for UV radiation.

Capsule films 24 and 26 are lamination films which connect solar cell arrangement 22 to both outer window body 18 and inner window body 20.

Solar cell arrangement 22 comprises a plurality of solar cell elements 28 which are disposed next to each other in the transverse and longitudinal roof direction and between which spaces 30 are formed. Solar cell elements 28 are connected to each other via electrical flat conductors 32 while also being connected to a vehicle network.

In the area of spaces 30, sandwich structure 16 is transparent in such a way that it is possible to see through to the vehicle interior below. However, solar cell elements 28 are opaque, meaning they do not allow a view into the vehicle interior.

In an edge area on the side facing solar cell arrangement 22, outer window body 18 has a glass frit 34, which limits the see-through surface of outer window body 18 in such a way that electrical flat conductors 32 are concealed and not visible from the outside of the pane.

Outer window body 18 has a reaction-cured sol-gel coating 44 on its outer surface facing the vehicle environment which reduces the reflectivity of outer window body 18 and is formed by a silicon dioxide compound.

Inner window body 20 is provided with a reflective layer 36 on its side facing away from solar cell arrangement 22, said reflective layer 36 being formed by a silver layer applied by vapor deposition using a CVD process.

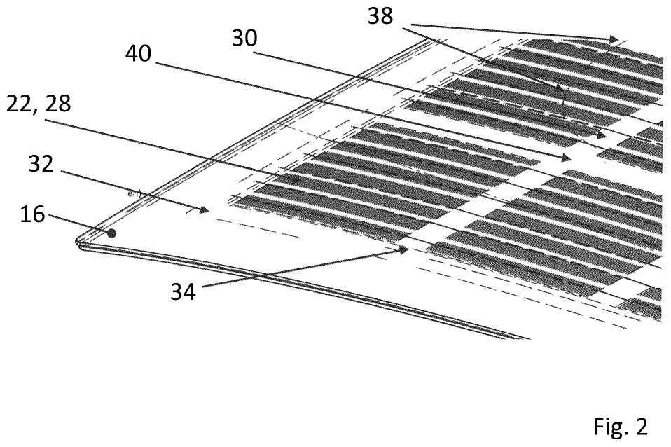

In an edge area extending to a headliner line 38 shown in FIG. 2, a glass frit 40 covering reflective layer 36 is also applied to the lower surface of inner window body 20. Glass frit 40 prevents the headliner (not shown in detail here), which extends from the roof side rails and the transverse roof rails to headliner line 38, from being visible through sandwich structure 16 from the outside of the vehicle.

Reflective layer 36 on the lower surface of inner window body 20 reflects in particular radiation Z, which passes from the vehicle environment through outer window body 18, capsule films 24, one of spaces 30, capsule film 26 and inner window body 20 and whose wavelength is in the UV range, in the direction of solar cell elements 28. This can increase the power yield that can be achieved by means of solar cell arrangement 22.

FIG. 4 shows a sandwich structure 16′ which largely corresponds to the one shown in FIGS. 1 to 3 and which can also form a vehicle window of a vehicle roof arrangement of the kind shown in FIG. 1. Sandwich structure 16′ differs from the one shown in FIGS. 1 to 3 in that it has a reflective layer 36′, which is disposed as a CVD silver coating on the upper surface or the side of inner window body 20 facing solar cell arrangement 22. On the inner side or lower surface facing the vehicle interior, inner window body 20 has a low-E or thermal coating 42, which is a vapor deposit coating of inner window body 20 and can comprise a metal oxide compound, an ITO compound, an FTO (fluorine-doped tin oxide) compound, a graphene-based compound and/or a silver compound. Thermal coating 42 is covered by glass frit 40, which extends to headliner line 38.

Otherwise, sandwich structure 16′ corresponds to the one shown in FIGS. 1 to 3.

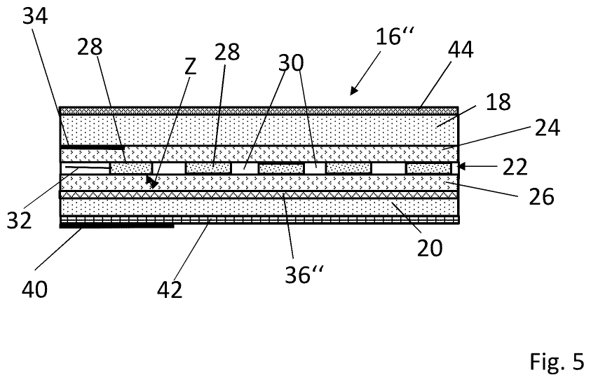

FIG. 5 shows another sandwich structure 16″, which again largely corresponds to the one shown in FIGS. 1 to 3, but differs from it in that it has a reflective layer 36″, which is not disposed on inner window body 20, but as a vapor deposit coating on the lower surface of capsule film 26, which forms the surface of capsule film 26 facing away from solar cell arrangement 22. Reflective layer 36″ also causes a reflection of radiation Z, which passes through spaces 30 between solar cell elements 28, in the direction of the lower surfaces of solar cell elements 28, so that the power yield of solar cell arrangement 22 is increased.

Otherwise, sandwich structure 16″ corresponds to the one shown in FIGS. 1 to 3.

### LIST OF REFERENCE SIGNS

10 vehicle roof arrangement
12 lid element
14 fixed roof element
16, 16′ 16″ sandwich structure
18 outer window body
20 inner window body
22 solar cell arrangement
24 capsule film
26 capsule film
28 solar cell element
30 space
32 flat conductor
34 glass frit
36, 36′, 36″ reflective layer
38 headliner line
40 glass frit
42 thermal coating
44 sol-gel coating

1. A vehicle window comprising:
a sandwich structure having an outer window body facing a vehicle environment and an inner window body facing a vehicle interior and having a solar cell arrangement, which is disposed between the outer window body and the inner window body, whose upper surface faces the outer window body and whose lower surface faces the inner window body and which comprises several solar cell elements, between which spaces are formed,
wherein at least one reflective layer, which is disposed on the side of the solar cell arrangement facing away from the outer window body and which reflects radiation, which passes through the spaces between the solar cell elements starting from the vehicle environment, at least partly in the direction of the solar cell elements.

2. The vehicle window according to claim 1, wherein the reflective layer is disposed on a capsule film which is adjacent to the solar cell arrangement.

3. The vehicle window according to claim 1, wherein the reflective layer is disposed on a surface of the inner window body facing the solar cell arrangement.

4. The vehicle window according to claim 1, wherein the reflective layer is disposed on a surface of the inner window body facing away from the solar cell arrangement.

5. The vehicle window according to claim 1, wherein the reflective layer comprises a vapor deposit coating.

6. The vehicle window according to claim 1, wherein the reflective layer comprises a film.

7. The vehicle window according to claim 1, wherein the reflective layer comprises a metal.

8. The vehicle window according to claim 1, wherein the solar cell arrangement is disposed between two capsule films and at least one of the capsule films is transparent to UV radiation.

9. The vehicle window according to claim 1, wherein the outer window body is modified in terms of its refractive index in a surface area on its side facing the vehicle environment.

10. The vehicle window according to claim 9, wherein the outer window body is provided with a sol-gel coating on the side facing the vehicle environment.

11. The vehicle window according to claim 1 to 10, wherein at least sections of the sandwich structure on the side facing the vehicle interior are provided with a glass frit.

12. The vehicle window according to claim 11, wherein the glass frit forms the reflective layer.

13. The vehicle window according to claim 11, wherein the reflective layer is disposed between the glass frit and the inner window body.

14. The vehicle window according to claim 7, wherein the metal reflective layer comprises silver and/or a metal oxide.

15. The vehicle window according to claim 14, wherein the metal oxide reflective layer comprises indium tin oxide.
